(19) United States
(12) Patent Application Publication
(10) Pub. No.: US 2002/0109416 A1
(43) Pub. Date: Aug. 15, 2002

(54) Touch sensitive circuit

(76) Inventors: James M. Lewis, Moulton, AL (US); Katherine D. Lewis, Moulton, AL (US)

Correspondence Address: WELSH & FLAXMAN LLC, 2341 JEFFERSON DAVIS HIGHWAY, SUITE 112, ARLINGTON, VA, 22202, US

(21) Appl. No.: 09/783,585

(22) Filed: Feb. 15, 2001

(51) Int. Cl. H03K 17/96

(52) U.S. Cl. 307/116

(57) ABSTRACT

A touch sensitive circuit including a touch pad positioned between a voltage divider circuit and a voltage source. The touch pad includes a first open connection electrically coupled to the voltage source and a second open connection electrically coupled to the voltage divider circuit, wherein the first open connection and the second open connection are adjacently positioned to permit an individual to simultaneously contact both the first open connection and the second open connection. The voltage divider circuit includes a resistor positioned between a ground and a metal oxide semiconductor gate. In use, contact by the skin of an individual electrically couples the first open connection and the second open connection, changing the voltage at the metal oxide semiconductor gate and thereby actuating the voltage divider circuit.

### BACKGROUND OF THE INVENTION

1. Field of the Invention

The invention relates to a touch sensitive circuit. More particularly, the invention relates to a touch sensitive circuit employing a digital CMOS gate to provide a simple, energy efficient design.

2. Description of the Prior Art

The prior art is replete with touch sensitive circuits operating based upon physical contact with a user thereof. For example, U.S. Pat. Nos. 3,621,307 to Raven et al., 4,211,959 to Deavenport et al., 4,289,980 to McLaughlin, 4,651,022 to Cowley, 4,764,717 to Tucker et al., 5,714,808 to Ansel et al. and 5,783,875 to Jaros, disclosure various devices employing touch sensitive technology. However, the touch sensitive circuits disclosed in these patents are very complex and consume large quantities of electricity.

While the complexity and energy consumption of these prior art circuits may be acceptable in environments where size and efficiency are not critical, the current lack of available touch sensitive circuits limits the potential growth of technology in the area of smaller, portable devices utilizing touch sensitive circuits. It is envisioned the enhanced development of more efficient touch sensitive circuits will provide technology developers with the opportunity to create portable touch sensitive devices offering consumers enhanced functionality. For example, it is envisioned that such portable, smaller touch sensitive circuitry would make possible interactive paper articles, ornaments, cards, etc. Additional devices for which small touch sensitive circuitry may have applications, include, but are not limited to, safety circuits where the touch sensitive circuit is used to verify the location of an operator's hands and children's toys.

With this in mind, those skilled in the art appreciate the need which currently exists for a portable, simple and energy efficient touch sensitive circuit. The present invention provides such a circuit.

### SUMMARY OF THE INVENTION

It is, therefore, an object of the present invention to provide a touch sensitive circuit. The touch sensitive circuit includes a touch pad positioned between a control circuit and a voltage source. The touch pad includes a first open connection electrically coupled to the voltage source and a second open connection electrically coupled to the control circuit. The first open connection and the second open connection are adjacently positioned to permit an individual to simultaneously contact both the first open connection and the second open connection. The control circuit also includes a resistor positioned between a ground and a metal oxide semiconductor gate. In use, contact by the skin of an individual electrically couples the first open connection and the second open connection converting the control circuit to a voltage divider circuit, changing the voltage at the metal oxide semiconductor gate and ultimately actuating the touch sensitive circuit.

It is also an object of the present invention to provide a touch sensitive circuit wherein the metal oxide semiconductor gate is a complementary metal oxide semiconductor.

It is also another object of the present invention to provide a touch sensitive circuit wherein the voltage source is a battery.

It is also a further object of the present invention to provide a touch sensitive circuit wherein the control circuit is a pull down circuit.

It is still a further object of the present invention to provide a greeting card. The greeting cards includes a substrate upon which a touch sensitive circuit is applied for actuating electronic components of the card. The touch sensitive circuit includes a touch pad positioned between a control circuit and a voltage source. The touch pad includes a first open connection electrically coupled to the voltage source and a second open connection electrically coupled to the control circuit. The first open connection and the second open connection are adjacently positioned to permit an individual to simultaneously contact both the first open connection and the second open connection. The control circuit includes a resistor positioned between a ground and a metal oxide semiconductor gate. In use, contact by the skin of an individual electrically couples the first open connection and the second open connection converting the control circuit to a voltage divider circuit, changing the voltage at the metal oxide semiconductor gate and ultimately actuating the touch sensitive circuit.

It is yet another object of the present invention to provide a greeting card wherein the touch pad is a foil border applied to the substrate.

It is also an object of the present invention to provide a greeting card wherein the metal oxide semiconductor gate is a complementary metal oxide semiconductor.

It is a further object of the present invention to provide a greeting card wherein the control circuit is a pull down circuit.

It is also an object of the present invention to provide a touch actuated apparatus including a substrate and a touch sensitive circuit applied to the substrate. The touch sensitive circuit is substantially as described above with regard to the greeting card.

Other objects and advantages of the present invention will become apparent from the following detailed description when viewed in conjunction with the accompanying drawings, which set forth certain embodiments of the invention.

### BRIEF DESCRIPTION OF THE DRAWINGS

FIG. 1 is a schematic of the present touch sensitive circuit without a user in contact with the touch pad.

FIG. 2 is a schematic of the present touch sensitive circuit with a user in contact with the touch pad.

FIG. 3 is a design of the present touch sensitive circuit applied to a printed circuit board.

FIG. 4 is a design of the present touch sensitive circuit incorporated in a greeting card.

### DESCRIPTION OF THE PREFERRED EMBODIMENTS

The detailed embodiment of the present invention is disclosed herein. It should be understood, however, that the disclosed embodiment is merely exemplary of the invention, which may be embodied in various forms. Therefore, the details disclosed herein are not to be interpreted as limited, but merely as the basis for the claims and as a basis for teaching one skilled in the art how to make and/or use the invention.

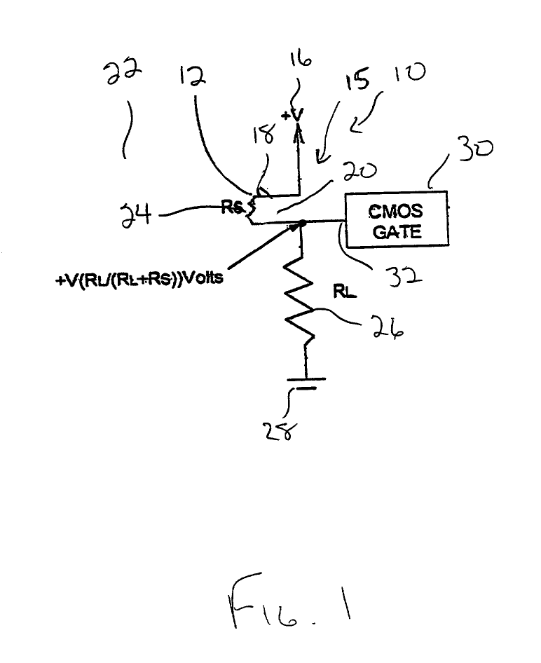

With reference to FIG. 1, a touch sensitive circuit 10 in accordance with the present invention is disclosed. In accordance with a first embodiment, the touch sensitive circuit 10 is generally composed of a touch pad 12, a control circuit 15 including a resistor 26 positioned between a ground 28 and a metal oxide semiconductor gate 30, and a voltage source 16 coupled to the control circuit 15 via the touch pad 12.

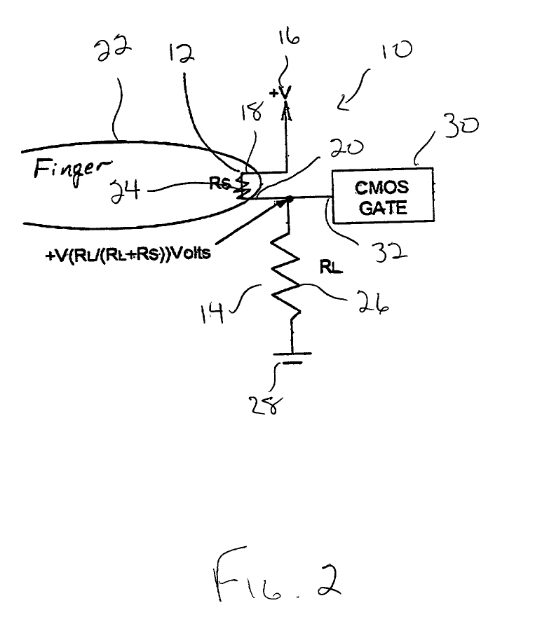

By positioning the touch pad 12 between a voltage source 16 and a control circuit 15, an individual activates, or completes, the present touch sensitive circuit 10 by simply pressing his or her skin, or flesh, against the touch pad 12 (see FIG. 2). Contact with the touch pad 12 in this way, permits the flow of current between the voltage source 16 and the control circuit 15. This change in voltage converts the control circuit 15 to a voltage divider circuit 14 (composed of the actuated touch pad 12, the resistor 26, ground 28 and metal oxide semiconductor gate 30), and ultimately actuates the touch sensitive circuit 10.

Where the touch pad 12 is not contacted by an operator, the voltage divider circuit 14 is not operational and the resistor 26, ground 28 and a metal oxide semiconductor gate 30 are generally considered to be a control circuit which maintains the gate biased off. In accordance with a preferred embodiment of the present invention, the control circuit is a pull-down circuit which maintains the gate bias off.

More particularly, the touch pad 12 includes a first open connection 18 electrically coupled to the voltage source 16 and a second open connection 20 electrically coupled to the control circuit 15. The first open connection 18 and the second open connection 20 are adjacently positioned to permit an individual to simultaneously contact both the first open connection 18 and the second open connection 20 with his or her finger tip 22. By simultaneously contacting both the first open connection 18 and the second open connection 20 the resistivity/conductivity 24 of the individuals skin permits the flow of electrical energy between the voltage source 16 and the ground 28, which completes the voltage divider circuit 14 and causes actuation in the manner described above.

As mentioned above, the actuated voltage divider circuit 14 generally includes an operator touching the touch pad 12, as well as a resistor 26 positioned between a ground 28 and a metal oxide semiconductor gate 30. In accordance with a preferred embodiment of the present invention, the metal oxide semiconductor gate 30 is a complementary metal oxide semiconductor (CMOS), although it is contemplated that a variety of metal oxide semiconductor based devices may work in accordance with the present invention. For example, this includes MOSFETs for using in turning lights on and off, as well as JFET and MOSFET based operational amplifiers.

In use, contact by the skin of an individual electrically couples the first open connection 18 and the second open connection 20. This provides a change of voltage in the control circuit which may be considered to convert the control circuit 15 to a voltage divider circuit 16. The change in voltage resulting in the completion of the voltage divider circuit 14 actuates the metal oxide semiconductor gate 30 by changing the voltage at the input 32 of the CMOS gate 30. Specifically, the resistivity of the human skin is in the kilo ohms per cm range. In accordance with the present invention, if the R_{L} resistor 26 is sized in the mega ohm range and the first and second open connections 18, 20 are spaced relatively close with sufficient surface area, the voltage at the CMOS inputs 32 approaches the value of +V source. Since a low voltage source of (3 to 5 volts or less) is sufficient and since very little current flows through the skin (typically 5 μAmps or less), the circuit is extremely safe.

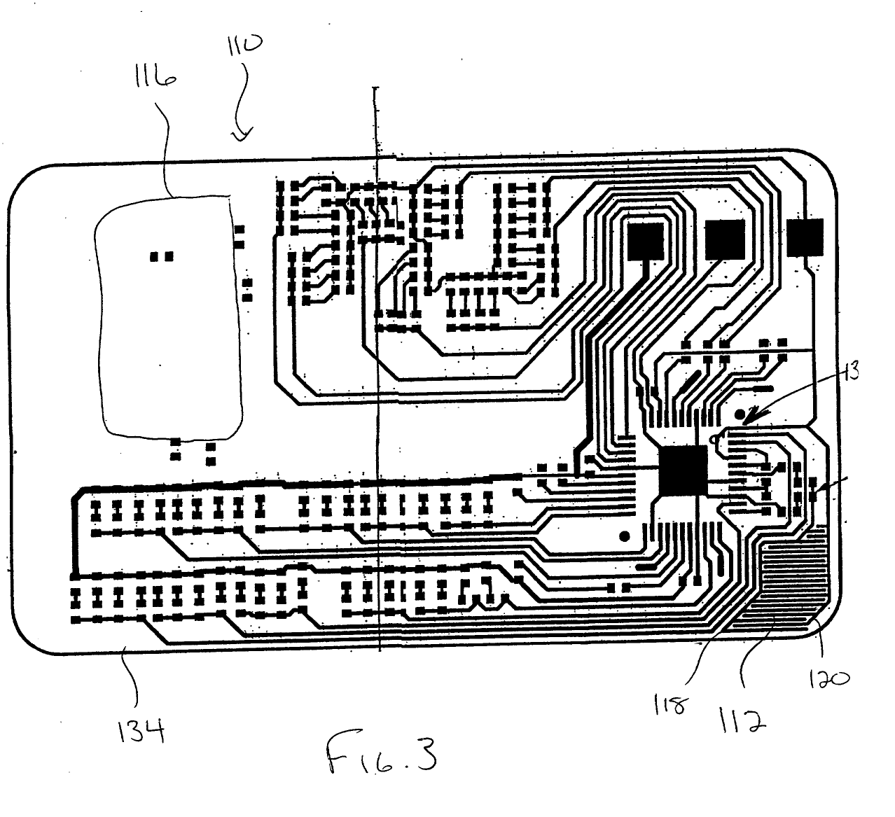

In accordance with a preferred embodiment of the present invention, and with reference to FIG. 3, the touch pad 112 is formed by applying conventional PCB traces in a pattern on the board 134 supporting the touch sensitive circuit 110 in accordance with the present invention. The traces constituting the first open connection 118 and the second open connection 120 are arranged to provide maximum surface area and minimum distance between the traces of the first open connection 118 and the second open connection 120. By providing first and second open connections 118, 120 with maximum surface area and minimum distance therebetween, the touch pad 112 in accordance with the present invention shows lower resistance levels, more efficiency and greater reliability.

As with the embodiment disclosed with reference to FIGS. 1 and 2, the embodiment disclosed in FIG. 3 employs a CMOS gate 130 coupled to a power source via the touch pad 112. Upon actuation of the CMOS gate 130, the remaining components of the circuit are actuated with electrical energy, for example, via a battery 116, to produce a desired result.

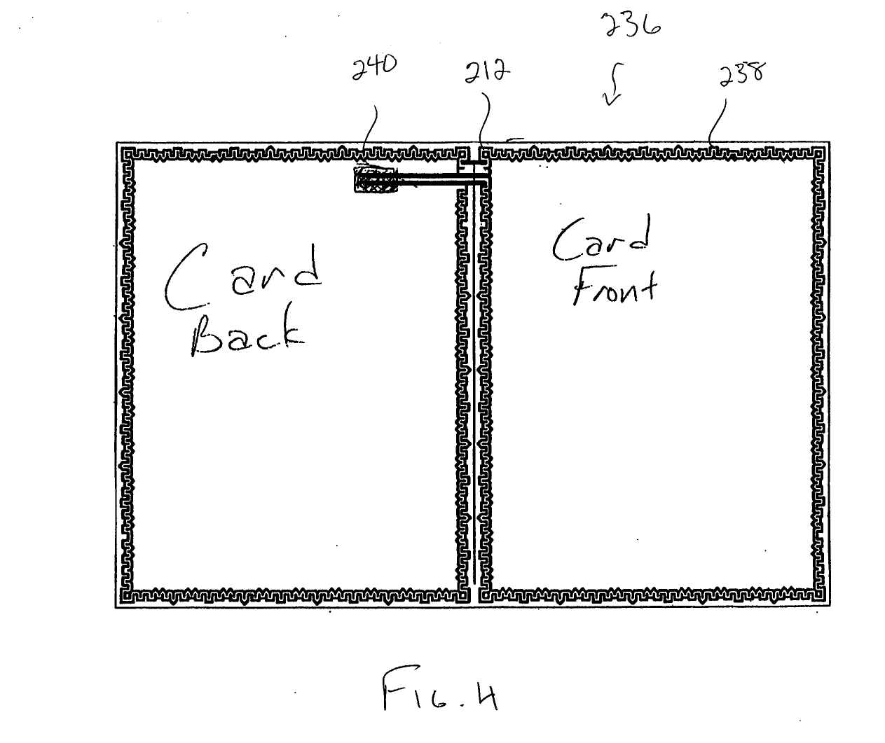

Referring to FIG. 4, an embodiment of the present touch sensitive circuit 210 used in the fabrication of an ornamental greeting card 236 is disclosed. In accordance with this embodiment the touch pad 212 is formed by applying foil 238 over paper such that a greeting card 236 is constructed with a decorative border that is actually part of the touch sensing circuit 240. Where such a design is implemented, the applied pattern can be applied to both the front and back of the greeting card to increase the likelihood of contact. As such, a card -may be activated simply by being touched as it is removed from its envelope, and does not have to be opened to start playing a tune or flashing lights. In addition, different foil patterns on the greeting card or circuit card can be used to activate different functions.

The utilization of metal oxide semiconductor technology in accordance with the present invention permits the fabrication of a small, energy efficient circuit well suited for applications like greeting cards, business cards, novelty items, cell phones and other similar devices.

In addition, the present touch sensitive circuit uses very small amounts of electricity. Specifically, the resistor used in accordance with the disclosed embodiment of the present invention is a pull down resistor. This pull down resistor is typically in the mega ohm range and, because of the isolated gate characteristics of the CMOS and MOSFETs gates used in accordance with preferred embodiments of the present invention, there is practically no current flow when the switch is not in contact (i.e., inactive). When the switch is touched, there is only enough flow of electrons to charge the MOSFET gate capacitance. The present touch sensitive circuit thereby offers a very efficient design as far as power consumption is concerned, making it very desirable for battery powered applications such as those discussed above.

While a preferred embodiment of the present invention is disclosed as using a pull down circuit, or resistor, (and it has been found that this is the most effective way to implement the present circuit), the circuit may be adapted to use a pull up resistor. Where a pull up resistor is used, contact with the touch pad efficiently pulls the input low in contrast to the positive input voltage created through the use of the pull down resistor. In addition, the circuit may be further provided with additional circuitry, such as, capacitors, other resistors and voltage suppression components, to protect the circuit from excessive static charges.

In addition, the embodiment disclosed above includes a single touch pad. However, those skilled in the art will readily appreciate the possible modification of the disclosed circuit to include multiple touch pads. It is contemplated that a multiple touch pad embodiment could be developed by repeating a complete circuit for each touch pad incorporated into the device.

While the preferred embodiments have been shown and described, it will be understood that there is no intent to limit the invention by such disclosure, but rather, is intended to cover all modifications and alternate constructions falling within the spirit and scope of the invention as defined in the appended claims.

1. A touch sensitive circuit, comprising:
a touch pad positioned between a control circuit and a voltage source, the touch pad including a first open connection electrically coupled to the voltage source and a second open connection electrically coupled to the control circuit, the first open connection and the second open connection being adjacently positioned to permit an individual to simultaneously contact both the first open connection and the second open connection;
the control circuit including a resistor positioned between a ground and a metal oxide semiconductor gate;
wherein contact by the skin of an individual electrically couples the first open connection and the second open connection converting the control circuit to a voltage divider circuit, changing the voltage at the metal oxide semiconductor gate and ultimately actuating the touch sensitive circuit.

2. The touch sensitive circuit according to claim 1, wherein the metal oxide semiconductor gate is a complementary metal oxide semiconductor.

3. The touch sensitive circuit according to claim 1, wherein the voltage source is a battery.

4. The touch sensitive circuit according to claim 1, wherein the control circuit is a pull down circuit.

5. A greeting card, comprising:
a substrate upon which a touch sensitive circuit is applied for actuating electronic components of the card;
the touch sensitive circuit includes:
a touch pad positioned between a control circuit and a voltage source, the touch pad including a first open connection electrically coupled to the voltage source and a second open connection electrically coupled to the control circuit, the first open connection and the second open connection being adjacently positioned to permit an individual to simultaneously contact both the first open connection and the second open connection;
the control circuit including a resistor positioned between a ground and a metal oxide semiconductor gate;
wherein contact by the skin of an individual electrically couples the first open connection and the second open connection converting the control circuit to a voltage divider circuit, changing the voltage at the metal oxide semiconductor gate and ultimately actuating the touch sensitive circuit.

6. The greeting card according to claim 5, wherein the touch pad is a foil border applied to the substrate.

7. The greeting card according to claim 5, wherein the metal oxide semiconductor gate is a complementary metal oxide semiconductor.

8. The greeting card according to claim 5, wherein the control circuit is a pull down circuit.

9. A touch actuated apparatus, comprising:
a substrate;
a touch sensitive circuit applied to the substrate, the touch sensitive circuit including:
a touch pad positioned between a voltage divider circuit and a voltage source, the touch pad including a first open connection electrically coupled to the voltage source and a second open connection electrically coupled to the voltage divider circuit, the first open connection and the second open connection being adjacently positioned to permit an individual to simultaneously contact both the first open connection and the second open connection;
the voltage divider circuit including a resistor positioned between a ground and a metal oxide semiconductor gate;
wherein contact by the skin of an individual electrically couples the first open connection and the second open connection changing the voltage at the metal oxide semiconductor gate and thereby actuating the voltage divider circuit.

10. The touch actuated apparatus according to claim 9, wherein the touch pad is a foil border applied to the substrate.

11. The touch actuated apparatus according to claim 9, wherein the metal oxide semiconductor gate is a complementary metal oxide semiconductor.

12. The touch actuated apparatus according to claim 9, wherein the voltage source is a battery.

13. The touch actuated apparatus according to claim 9, wherein the control circuit is a pull down circuit.
